(19) United States
(12) Patent Application Publication
(10) Pub. No.: US 2012/0306488 A1
(43) Pub. Date: Dec. 6, 2012

(54) SPIN-VALVE MAGNETORESISTANCE STRUCTURE AND SPIN-VALVE MAGNETORESISTANCE SENSOR

(75) Inventors: KUANG-CHING CHEN, Changhua County (TW); Ta-Yung Wong, Hsinchu (TW); Tai-Lang Tang, Taichung (TW); Chien-Min Lee, Hsinchu County (TW)

(73) Assignee: Voltafield Technology Corporation, Jhuhei City (TW)

(21) Appl. No.: 13/427,879

(22) Filed: Mar. 22, 2012

(30) Foreign Application Priority Data
Jun. 1, 2011 (TW) 100119286

(51) Int. Cl. G01R 33/09; B32B 7/02

(52) U.S. Cl. 324/252; 428/212

(57) ABSTRACT

A spin-valve magnetoresistance structure includes a first magnetoresistance layer having a fixed first magnetization direction, a second magnetoresistance layer disposed on a side of the first magnetoresistance layer and having a variable second magnetization direction, and a spacer disposed between the first magnetoresistance layer and the second magnetoresistance layer. The second magnetization direction is at an angle in a range from 30 to 60 degrees or from 120 to 150 degrees to the first magnetization direction when the intensity of an applied external magnetic field is zero. The second magnetization direction varies with the external magnetic field thereby changing an electrical resistance of the spin-valve magnetoresistance structure. A spin-valve magnetoresistance sensor based on the spin-valve magnetoresistance structure is also provided.

### FIELD OF THE INVENTION

The present invention relates generally to magnetoresistance sensors, and more particularly to a spin-valve magnetoresistance structure and a spin-valve magnetoresistance sensor.

### BACKGROUND OF THE INVENTION

The dependence of the electrical resistance of a body on an external magnetic field is called magnetoresistance. Magnetoresistance sensors are used to detect the influence of a magnetic field, and have been widely applied in various electronic products and circuits. Generally, magnetoresistance sensors are based on the mechanisms including anisotropic magnetoresistance (AMR), giant magnetoresistance (GMR), tunneling magnetoresistance (TMR), or combinations thereof Currently, magnetoresistance sensors can be integrated into integrated circuits (IC) to achieve the object of miniaturization and highly integration. Therefore, there is a desire to provide a compact spin-valve magnetoresistance sensor.

### SUMMARY OF THE INVENTION

The present invention provides a magnetoresistance sensor having a compact structure and simplified manufacturing process.

In one embodiment, a spin-valve magnetoresistance structure includes a first magnetoresistance layer having a fixed first magnetization direction, a second magnetoresistance layer disposed on a side of the first magnetoresistance layer and having a variable second magnetization direction, and a spacer disposed between the first magnetoresistance layer and the second magnetoresistance layer. The second magnetization direction is at an angle in a range from 30 to 60 degrees or from 120 to 150 degrees to the first magnetization direction when the intensity of an applied external magnetic field is zero. The second magnetization direction varies with the external magnetic field thereby changing an electrical resistance of the spin-valve magnetoresistance structure.

In one embodiment, a spin-valve magnetoresistance sensor includes a first pair of magnetoresistance structure and a second pair of magnetoresistance structure. The first pair of magnetoresistance structure each includes a first magnetoresistance layer having a fixed first magnetization direction, a second magnetoresistance layer disposed on a side of the first magnetoresistance layer and having a variable second magnetization direction; and a first spacer disposed between the first magnetoresistance layer and the second magnetoresistance layer. The second magnetization direction is at an angle in a range from 30 to 60 degrees or from 120 to 150 degrees to the first magnetization direction when the intensity of an applied external magnetic field is zero. The second magnetization direction varies with the external magnetic field thereby changing an included angle between the first magnetization direction and the second magnetization direction and further changing a first electrical resistance of the spin-valve magnetoresistance structure.

The second pair of magnetoresistance structure each includes a third magnetoresistance layer having a fixed third magnetization direction, a fourth magnetoresistance layer disposed on a side of the third magnetoresistance layer and having a variable fourth magnetization direction, and a second spacer disposed between the third magnetoresistance layer and the fourth magnetoresistance layer. The third magnetization direction is the same to the first magnetization direction. The fourth magnetization direction is at an angle in a range from 30 to 60 degrees or from 120 to 150 degrees to the third magnetization direction when the intensity of an applied external magnetic field is zero. The fourth magnetization direction is perpendicular to the second magnetization direction, and the fourth magnetization direction varies with the external magnetic field thereby changing an included angle between the fourth magnetization direction and the third magnetization direction and further changing a second electrical resistance of the spin-valve magnetoresistance structure. The first pair of magnetoresistance structures and the second pair of magnetoresistance structures are electrically connected to construct a Wheatstone bridge.

Above spin-valve magnetoresistance sensor includes two pairs of spin-valve magnetoresistance structures which present different magnetic and electrical response to applied external magnetic fields. The two pairs of spin-valve magnetoresistance structures have the same and fixed first magnetization direction and third magnetization direction. The second magnetization direction, the fourth magnetization direction is at an angle of 45 degrees to the first magnetization direction, the third magnetization direction, respectively, when the intensity of the external magnetic field is zero, wherein the second magnetization direction is orthogonal to the fourth magnetization direction.

When the intensity of the external magnetic field isn't zero, the second magnetization direction and the fourth magnetization direction would vary with the external magnetic field thereby changing the electrical resistances of the two pairs of spin-valve magnetoresistance structures. Thus, the external magnetic field can be measured according to the relation between the magnetoresistance of the spin-valve magnetoresistance sensor and the external magnetic field. As such, the coils for adjusting the magnetization direction or magnetic shielding layers on a diagonal for fixing the magnetization direction can be omitted in spin-valve magnetoresistance sensors. Thus, the structure and manufacturing process of spin-valve magnetoresistance sensors are simplified; the cost, the complexity, and the volume of spin-valve magnetoresistance sensors are also reduced.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic view of a spin-valve magnetoresistance sensor in accordance with a first embodiment;

FIG. 1B is a schematic view illustrating cross sectional views of spin-valve magnetoresistance structures of the spin-valve magnetoresistance sensor shown in FIG. 1A;

FIG. 2A is a schematic view of a spin-valve magnetoresistance sensor in accordance with a second embodiment;

FIG. 2B is a schematic view illustrating cross sectional views of spin-valve magnetoresistance structures of the spin-valve magnetoresistance sensor shown in FIG. 2A;

FIG. 3A is a cross sectional schematic view of a spin-valve magnetoresistance structure in accordance with a third embodiment;

FIG. 3B is a top schematic view of the spin-valve magnetoresistance structure in accordance with the third embodiment;

FIGS. 4 to 7 are schematic views illustrating that the second magnetization direction of the spin-valve magnetoresistance structure shown in FIG. 3B varies with the external magnetic field;

FIG. 8 is a curve graph illustrating the correspondence between the external magnetic field and the electrical resistance of the spin-valve magnetoresistance structure of FIG. 3B;

FIG. 9A is a schematic view illustrating a spin-valve magnetoresistance sensor in accordance with a fourth embodiment;

FIG. 9B is a cross sectional schematic view of a first pair of spin-valve magnetoresistance structures in the spin-valve magnetoresistance sensor shown in FIG. 9A;

FIG. 9C is a cross sectional schematic view of a second pair of spin-valve magnetoresistance structures in the spin-valve magnetoresistance sensor shown in FIG. 9A;

FIGS. 10 and 11 are schematic views illustrating the spin-valve magnetoresistance sensor shown in FIG. 9A is applied with different external magnetic fields;

FIG. 12A is a curve graph showing output voltages V1 and V2 of the spin-valve magnetoresistance sensor of FIG. 9A corresponding to different external magnetic fields; and

FIG. 12B is a curve graph showing the relation between V2−V1 and the external magnetic field.

FIG. 12C is a curve graph showing the sweep curve of the output voltage difference (V2−V1) in accordance with the present embodiment.

FIG. 12D is a curve graph showing detailed measurement focusing on the specific magnetic field range (−10 Oe to +10 Oe).

### DETAILED DESCRIPTION OF PREFERRED EMBODIMENTS

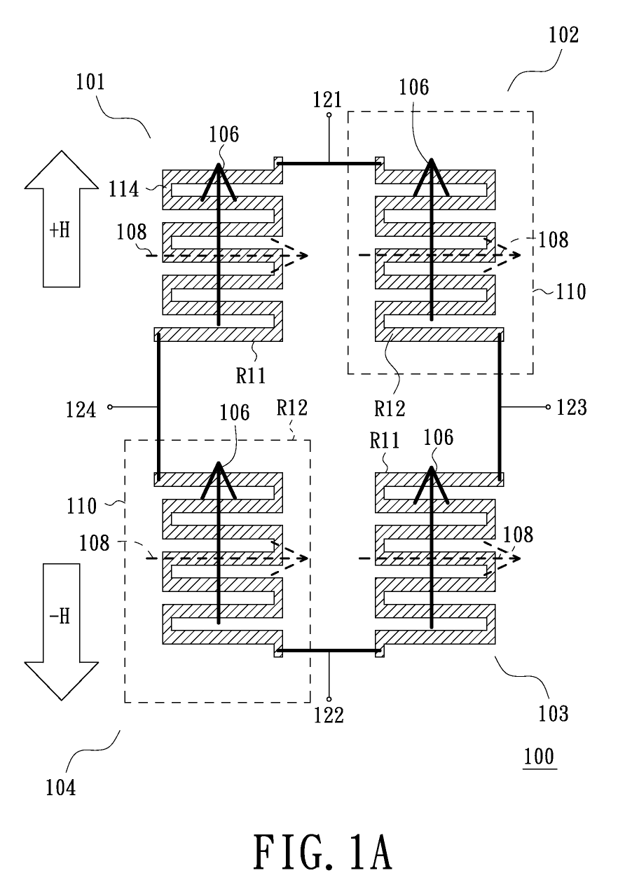

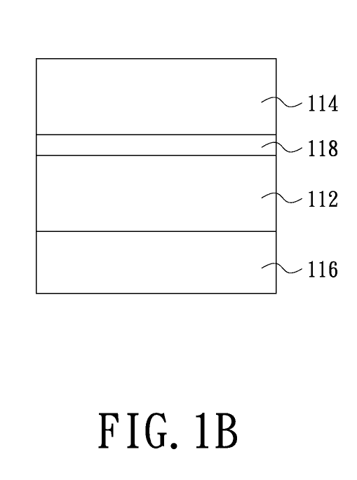

FIG. 1A shows a schematic view of a known spin-valve magnetoresistance sensor 100 in accordance with a first embodiment, which mainly includes a first pair of spin-valve magnetoresistance structures 101, 103, and a second pair of spin-valve magnetoresistance structures 102, 104. The spin-valve magnetoresistance structures 101, 102, 103, 104 are connected to construct a Wheatstone bridge, which includes an input terminal 121, a reference terminal 122, a first output terminal 123 (outputting voltage V1) and a second output terminal 124 (outputting voltage V2).

The first pair of spin-valve magnetoresistance structures 101 and 103 is used to detect the variance of the magnetic fields H+, and H− to produce magnetoresistance signals, while the second pair of spin-valve magnetoresistance structures 102 and 104 is used to provide reference resistances. The two pairs of spin-valve magnetoresistance structures 101, 102, 103, 104 have the same structure, and the cross sectional views thereof are illustrated in FIG. 1B.

Each of the spin-valve magnetoresistance structures includes an exchange bias layer 116, a pinned layer 112, a spacer 118, and a free layer 114. Magnetization directions 106 of pinned layers 112 of the two pairs of spin-valve magnetoresistance structures are the same and are parallel to the sensing axis direction of the external magnetic field. Further, the magnetization directions 106 are also at an angle of 90 degrees to a magnetization direction 108 of the free layer 114 when the intensity of the external magnetic field is zero.

To detect the variance of the external magnetic fields, the spin-valve magnetoresistance sensor needs a magnetic shielding layer 110 to cover the second pair of spin-valve magnetoresistance structures 102 and 104 such that the magnetization directions 108 of the free layers 114 and the electrical resistance R12 of the second pair of magnetoresistance structures 102, 104 are substantially fixed at a constant value. In contrast, if there is no magnetic shielding layer 110, the external magnetic field would change the magnetization direction 108 of the free layers 114 of the first pair of spin-valve magnetoresistance structures 101, 103. As a result, the included angle between the magnetization directions 108 and the magnetization directions 106 of the pinned layers 112 is also changed. As a consequence, the electrical resistance R11 varies thereby varying the output voltages V1, V2 of the Wheatstone bridge. The above spin-valve magnetoresistance sensor needs a magnetic shielding layer 110 to cover the second pair of magnetoresistance structures 102 and 104 that provides the reference resistance.

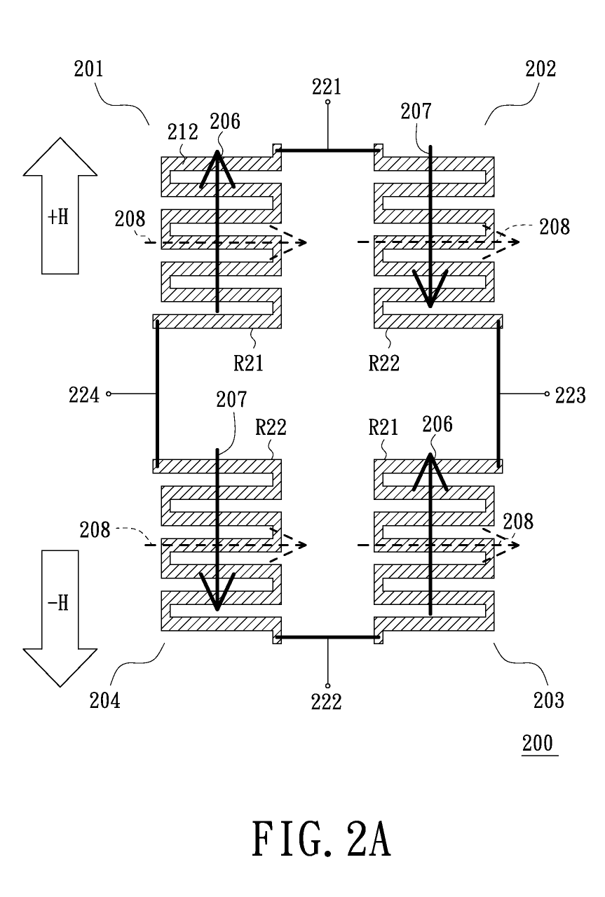

FIG. 2A is a schematic view of another spin-valve magnetoresistance sensor 200 in accordance with a second embodiment. Similarly, the spin-valve magnetoresistance sensor 200 is also constructed as a Wheatstone bridge, which includes a first pair of spin-valve magnetoresistance structures 201, 203, and a second pair of spin-valve magnetoresistance structures 202, 204. The magnetoresistance sensor 200 further includes an input terminal 221, a reference terminal 222, a first output terminal 223 (outputting voltage V1) and a second output terminal 224 (outputting voltage V2).

The spin-valve magnetoresistance sensor 200 differs from the spin-valve magnetoresistance sensor 100 in that the two pairs of magnetoresistance structures 201, 203, 202, 204 are all used to detect the variance of the external magnetic field to produce magnetoresistance signals. The two pairs of spin-valve magnetoresistance structures 201, 202, 203, 204 have the same structure, and the cross sectional views thereof are illustrated in FIG. 2B. Each of the spin-valve magnetoresistance structures includes an exchange bias layer 214, a pinned layer 210, a spacer 216, and a free layer 212. Referring to FIG. 2A, the pinned layers 210 of the first pair of spin-valve magnetoresistance structures 201, 203 has the same and fixed magnetization directions 206, and the second pair of magnetoresistance structures 202, 204 has another magnetization direction 207. The magnetization direction 206 and the magnetization direction 207 are opposite to each other, and are parallel to the sensing axis direction of the external magnetic field. The magnetization directions 208 of the free layers of the two pairs of spin-valve magnetoresistance structures are the same, and are perpendicular to the magnetization directions 206, 207 of the pinned layers when the intensity of the external magnetic field is zero.

However, the included angle between the magnetization directions 208 of the free layers and the magnetization directions 206, 207 of the pinned layers varies with the external magnetic field. To achieve the two opposite and parallel magnetization directions in the pinned layers, a coil for adjusting the magnetization directions is required in each of the two pairs of spin-valve magnetoresistance structures 201, 203, 202, 204. The coil generates a magnetic field when a current is applied thereto at a high temperature environment, which is used to control that the magnetization directions 206, 207 of the pinned layers are opposite and parallel to each other. That is, the magnetization directions 206, 207 are at an angle of 180 degrees to each other.

The external magnetic field would change the magnetization directions 208 of the free layers such that the included angle between the magnetization directions 208 and the magnetization directions 206 also changes. As a result, an electrical resistance R21 of the first pair of spin-valve magnetoresistance structure 201, 203 also varies. Similarly, the external magnetic field also changes the included angle between the magnetization direction 208 of the free layers and the magnetization direction 207 of the pinned layers. As a consequence, an electrical resistance R22 of the second pair of spin-valve magnetoresistance structures 202, 204 is also changed.

Since the variance of the included angles between the magnetization direction 208 of the free layers and the magnetization directions 206, 207 are different; accordingly, the electrical resistance R21 and the electrical resistance R22 are also different, which further changes the output voltages (V1, V2) of the Wheatstone bridge.

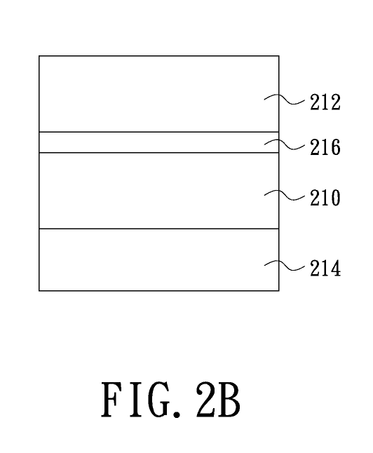

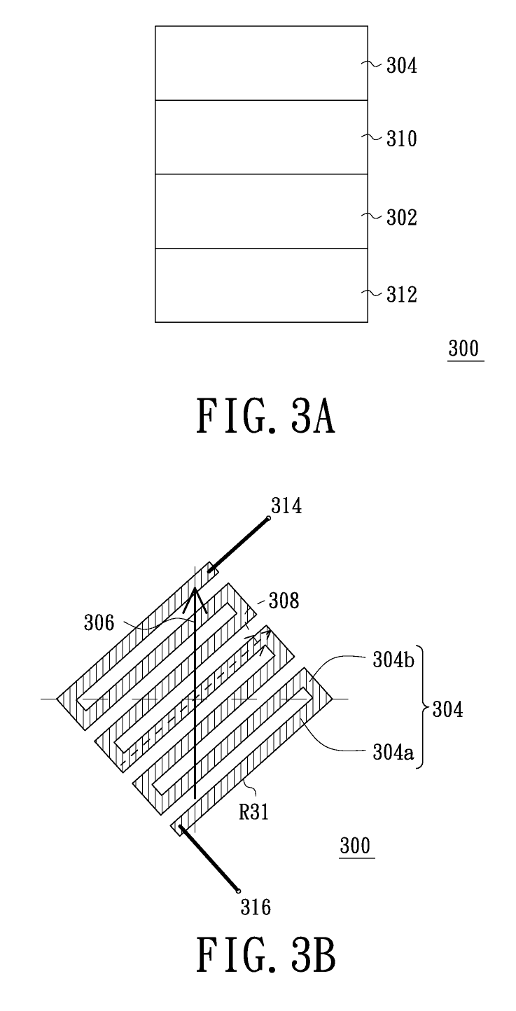

FIG. 3A is a cross sectional schematic view of a spin-valve magnetoresistance structure 300 in accordance with a third embodiment. Referring to FIG. 3A, the spin-valve magnetoresistance structure 300 includes a first magnetoresistance layer 302, a second magnetoresistance layer 304 and a spacer 310. The second magnetoresistance layer 304 is disposed at a side of the first magnetoresistance layer 302, and the spacer 310 is interposed between the first magnetoresistance layer 302 and the second magnetoresistance layer 304 to connect the two magnetoresistance layers. An exchange bias layer 312 is further disposed on a side of the first magnetoresistance layer 302 that is away from the spacer 310 to fix a first magnetization direction 306 of the first magnetoresistance layer 302.

In other embodiments, the spacer 310 can also be disposed on the second magnetoresistance layer 304, and then the first magnetoresistance layer 302 and the exchange bias layer 312 can be sequentially disposed on the spacer 310. The spin-valve magnetoresistance structure 300 can be based on the mechanism selected from a group consisting of spin-valve giant magnetoresistance or spin-valve tunneling magnetoresistance.

FIG. 3B is a top schematic view of the spin-valve magnetoresistance structure 300 in accordance with a third embodiment. Referring to FIG. 3B, in the present embodiment, the first magnetoresistance layer 302 has a fixed magnetization direction 306, and the second magnetoresistance layer 304 has a variable magnetization direction 308. In addition, the magnetoresistance structure 300 includes a number of first portions 304a and a number of second portions 304b that is shorter than the first portions 304a. The first portions 304a are serially connected by the second portions 304b to construct a serpentine structure. More specifically, the first portions 304a and the second portions 304b are alternately arranged in the serpentine structure. Besides, the first portions 304a and the second portions 304b may consists of different materials.

Additionally, in other embodiments, the first portions 304a and the second portions 304b can also have one-on-one correspondence, and the first portions 304a are serially connected by the second portion 304b to construct a serpentine structure. Moreover, metal wires electrically connected to a first electrode 314 and a second electrode 316 can be disposed at two ends of the spin-valve magnetoresistance structure 300, respectively. The spin-valve magnetoresistance structure 300 can detect the external magnetic field that is perpendicular to the first magnetization direction 306. The second magnetization direction 308 is parallel to the first portions 304a, and an inner product of the first magnetization direction 306 and the second magnetization direction 308 isn't equal to zero when the intensity of the external magnetic field is zero. The included angle between the first magnetization direction 306 and the second magnetization direction 308 can be in a range from 30 to 60 degrees or in a range 120 to 150 degrees. In one embodiment, the included angle would be 45 degrees.

When the intensity of the external magnetic field is not zero, the second magnetization direction 308 would vary, which results in that the included angle between the first magnetization direction 306 and the second magnetization direction 308 also varies. Also, an electrical resistance R31 of the spin-valve magnetoresistance structure 300 is changed.

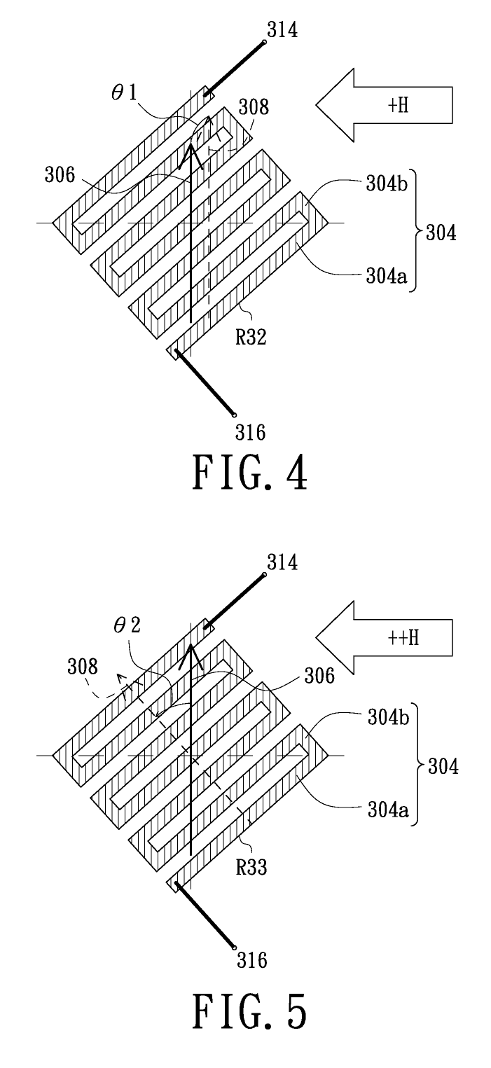

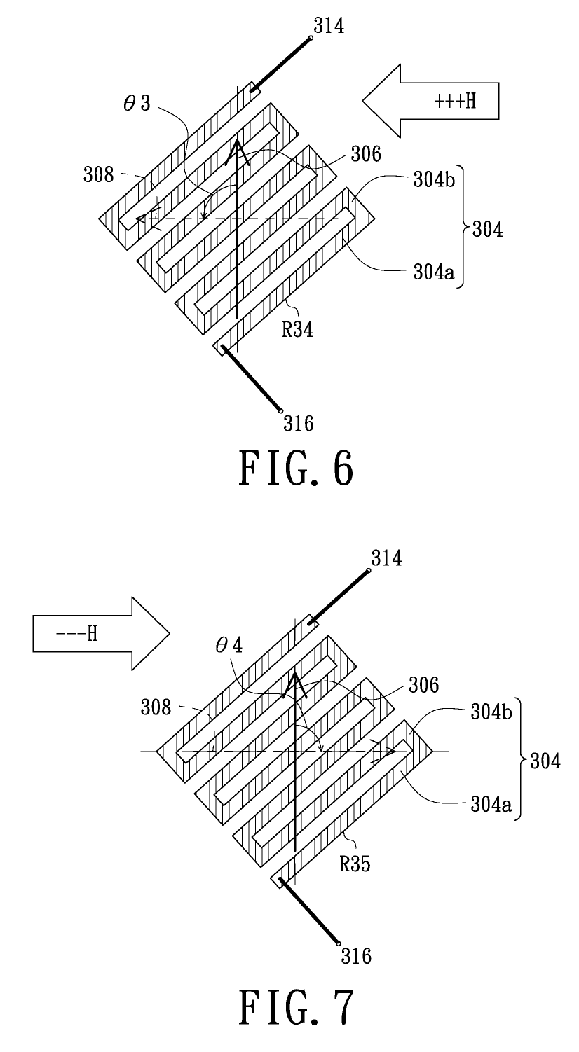

FIGS. 4 to 7 are schematic views illustrating that the second magnetization direction 308 varies with the external magnetic field. As shown in FIGS. 4 to 6, the applied external magnetic field is perpendicular to the first magnetization direction 306, and the intensity thereof is +H, ++H, +++H (the number of plus symbols indicates the intensity), respectively. Accordingly, the second magnetization direction 308 varies with the external magnetic field and is at a first angle θ1, a second angle θ2, and a third angle θ3 to the first magnetization direction 306, respectively. The electrical resistances of the spin-valve magnetoresistance structures are R32, R33, R34, respectively.

Referring to FIG. 7, if an external magnetic field with an opposite direction and an intensity of −−−H is applied, the second magnetization direction 308 would be at an angle of θ4 to the first magnetization direction 306, and the electrical resistance of the spin-valve magnetoresistance structure would be R35. It is to be noted that magnetic fields of +H and −H have the same intensity but opposite directions.

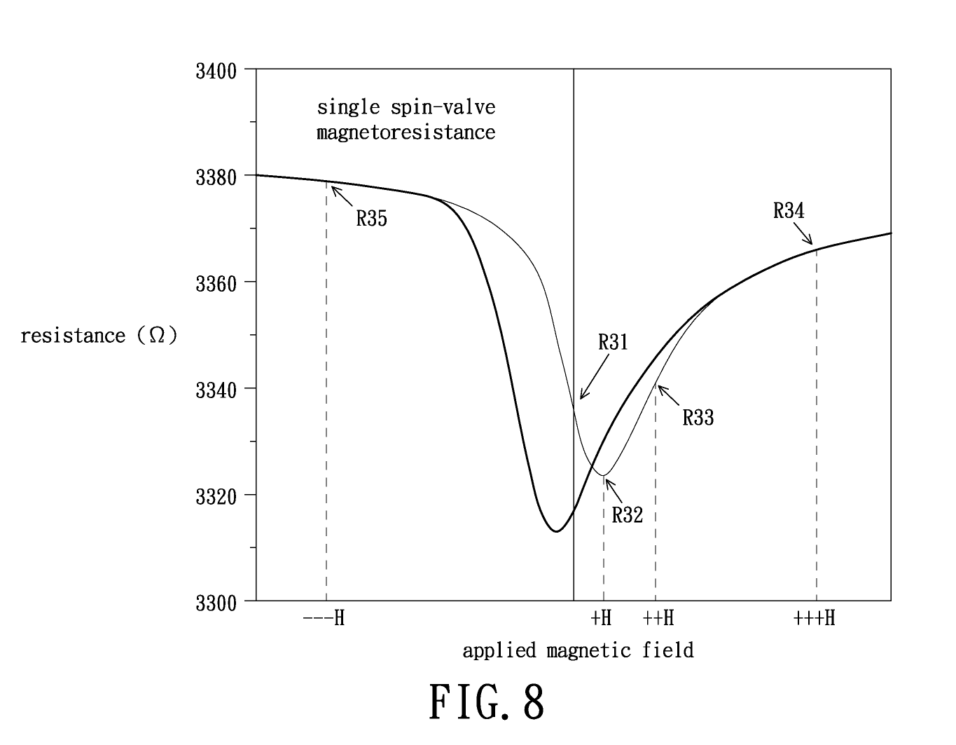

As shown in FIGS. 4 to 7, the intensity and direction of the external magnetic field change the included angle between the first magnetization direction 306 and the second magnetization direction 308, and thus also change the electrical resistance of the spin-valve magnetoresistance structure. In other words, the intensity of the external magnetic field can be measured by measuring the electrical resistance of the spin-valve magnetoresistance structure. The measured results of FIGS. 3 to 7 are shown in FIG. 8. FIG. 8 is a curve graph illustrating the correspondence between the external magnetic field (varying from zero to +++H, from +++H to zero, from zero to −−−H, and from −−−H to zero) and the electrical resistance of the spin-valve magnetoresistance structure.

Referring to FIG. 8, if the external magnetic field is greater than +++H or lower than −−−H, the electrical resistance of the spin-valve magnetoresistance structure inclines to a threshold value and can't reflect the intensity of the external magnetic field. Besides, if the external magnetic field varies from +++H back to zero, the electrical resistance can't back to the original value R31, and this phenomena is called magnetic hysteresis effect. At this time, an external magnetic field stronger than −−−H is applied and then the external magnetic field goes back to zero. After these steps, the electrical resistance of the spin-valve magnetoresistance structure goes back to the original value R31. These steps are used to reset the second magnetization direction 308 to its original state (e.g., the state when the intensity of the external magnetic field is zero and there is no external magnetic field is applied).

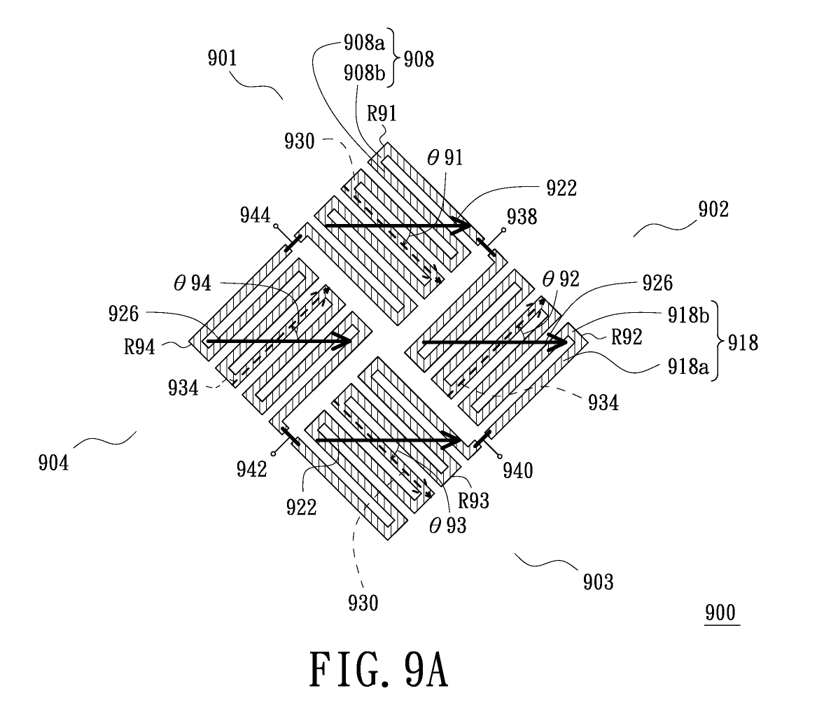

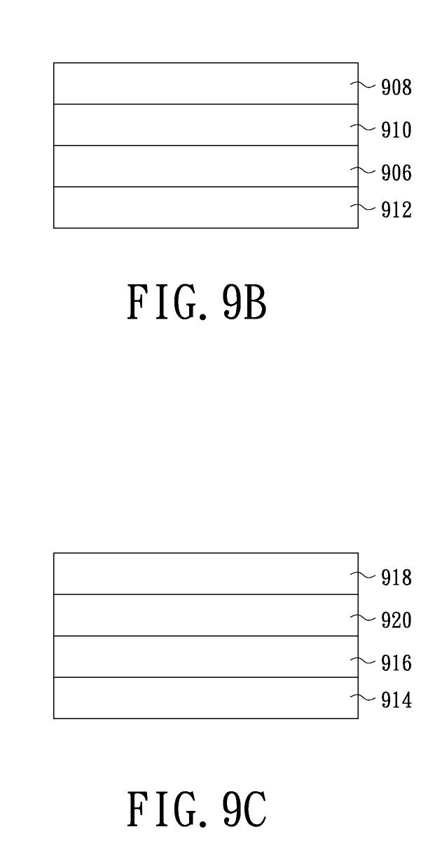

FIG. 9A is a schematic view illustrating a spin-valve magnetoresistance sensor 900 in accordance with a fourth embodiment, which includes a Wheatstone bridge consists of above spin-valve magnetoresistance structures. Referring to FIG. 9A, the magnetoresistance sensor 900 includes a first pair of spin-valve magnetoresistance structures 901, 903 and a second pair of spin-valve magnetoresistance structures 902, 904 arranged in a circular path. Furthermore, the four spin-valve magnetoresistance structures 901, 902, 903, 904 are connected end-to-end (901 902 903 904 901). Besides, a connecting line of the first pair of magnetoresistance structures 901, 903 crosses over or is orthogonal to a connecting line of the second pair of magnetoresistance structures 902, 904. The spin-valve magnetoresistance structures 901 and 902 are connected to an input terminal 938; the spin-valve magnetoresistance structures 902 and 903 are connected to a first output terminal 940; the spin-valve magnetoresistance structures 903 and 904 are connected to a reference terminal 942; and the spin-valve magnetoresistance structures 904 and 901 are connected to a second output terminal 944.

In the present embodiment, a first magnetoresistance layer 906 of the first pair of spin-valve magnetoresistance structures 901, 903 has a fixed magnetization direction 922, and the second magnetoresistance layer 908 has a variable second magnetization direction 930. Each of the first pair of spin-valve magnetoresistance structures 901, 903 includes a number of longer first portions 908a and a number of shorter second portions 908b. The first portions 908a are serially connected by the second portions 908b to construct a serpentine structure. More specifically, the first portions 908a and the second portions 908b are alternately arranged in the serpentine structure. Besides, the first portions 908a and the second portions 908b may consists of different materials.

Additionally, in other embodiments, the first portions 908a and the second portions 908b can also have one-on-one correspondence, and the first portions 908a are serially connected by the second portions 908b to a serpentine structure. The second magnetoresistance layer 908 has a variable second magnetization direction 930. The second magnetization direction 930 is parallel to the first portions 908a and an inner product thereof to the first magnetization direction 922 isn't equal to zero when the intensity of the external magnetic field is zero. An included angle θ91 between the first magnetization direction 922 and the second magnetization direction 930 can be in a range from −30 to −60 degrees or in a range −120 to −150 degrees. In one embodiment, the included angle would be −45 degrees.

FIG. 9B is a cross sectional schematic view of the first pair of spin-valve magnetoresistance structures. Referring to FIG. 9B, a spacer 910 is interposed between the first magnetoresistance layer 906 and the second magnetoresistance layer 908 to connect the two magnetoresistance layers. Furthermore, an exchange bias layer 912 is disposed on a side of the first magnetoresistance layer 906 that is away from the spacer 910 to fix the first magnetization direction 922 of the first magnetoresistance layer 906.

Referring again to FIG. 9A, a third magnetoresistance layer 916 of the second pair of spin-valve magnetoresistance structures 902, 904 has a fixed third magnetization direction 926, and the third magnetization direction 926 is the same to the first magnetization direction 922. A fourth magnetoresistance layer 918 has a variable fourth magnetization direction 934. Each of the second pair of spin-valve magnetoresistance structures 902, 904 includes a number of longer first portions 918a and a number of shorter second portions 918b. The first portions 918a are serially connected by the second portions 918b to construct a serpentine structure. More specifically, the first portions 918a and the second portions 918b are alternately arranged in the serpentine structure. Besides, the first portions 918a and the second portions 918b may consists of different materials.

Additionally, in other embodiments, the first portions 918a and the second portions 918b can also have one-on-one correspondence, and the first portions 918a are serially connected by the second portions 918b to construct a serpentine structure. The fourth magnetization direction 934 is perpendicular to the second magnetization direction 930, and an inner product thereof to the third magnetization direction 926 isn't equal to zero when the intensity of the external magnetic field is zero. An included angle θ92 between the third magnetization direction 926 and the fourth magnetization direction 934 can be in a range from 30 to 60 degrees or in a range from 120 to 150 degrees. In one embodiment, the included angle would be 45 degrees.

FIG. 9C is a cross sectional schematic view of the second pair of spin-valve magnetoresistance structures. Referring to FIG. 9C, a second spacer 920 is interposed between the third magnetoresistance layer 916 and the fourth magnetoresistance layer 918 to connect the two magnetoresistance layers. Furthermore, an exchange bias layer 914 is disposed on a side of the third magnetoresistance layer 916 that is away from the spacer 920 to fix the third magnetization direction 926 of the third magnetoresistance layer 916. In the present embodiment, the first magnetoresistance layer 906, the second magnetoresistance layer 908, the third magnetoresistance layer 916, and the fourth magnetoresistance layer 918 are not limited to be consisting of the same materials, and the magnetoresistance structures can be based on the mechanism selected form a group consisting of spin-valve giant magnetoresistance and spin-valve tunneling magnetoresistance.

In other embodiments, if the intensity of the external magnetic field (perpendicular to the first magnetization direction 922 and the third magnetization direction 926) isn't equal to zero, the second magnetization direction 930 and the fourth magnetization direction 934 would vary with the intensity of the external magnetic field. As a result, the included angle between the first magnetization direction 922 and the second magnetization direction 930, and the included angel between the third magnetization direction 926 and the fourth magnetization direction 934 also vary at different degrees (θ 91=θ93≠θ 92=θ 94), respectively. Sequentially, electrical resistances R91, R93 of the first pair of spin-valve magnetoresistance structures 901, 903, and electrical resistances R92, R94 of the second pair of magnetoresistance structures 902, 904 are also varied (R91=R93≠R92=R94).

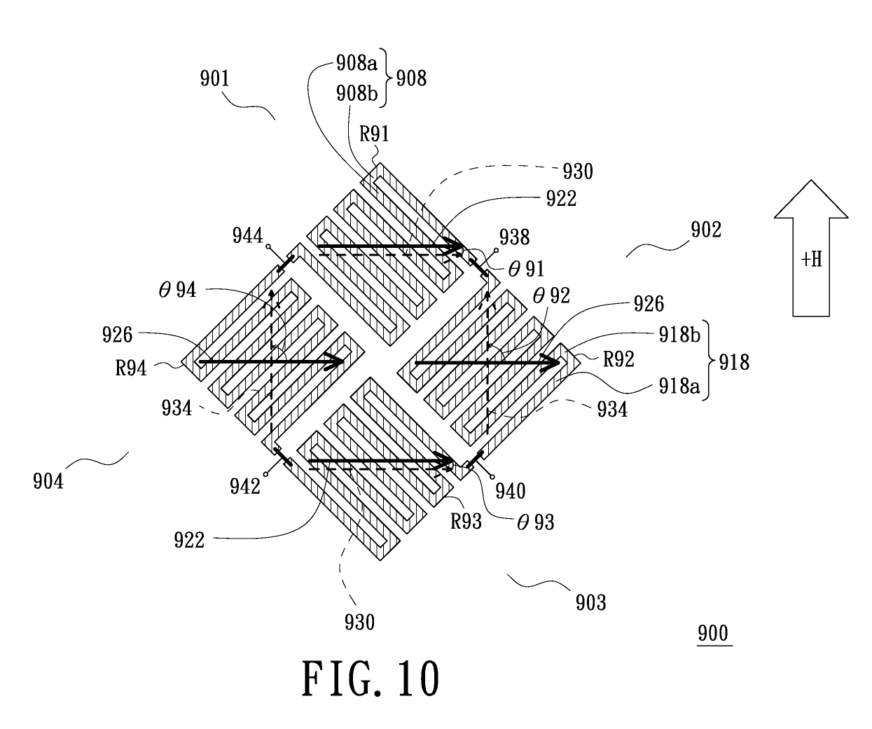

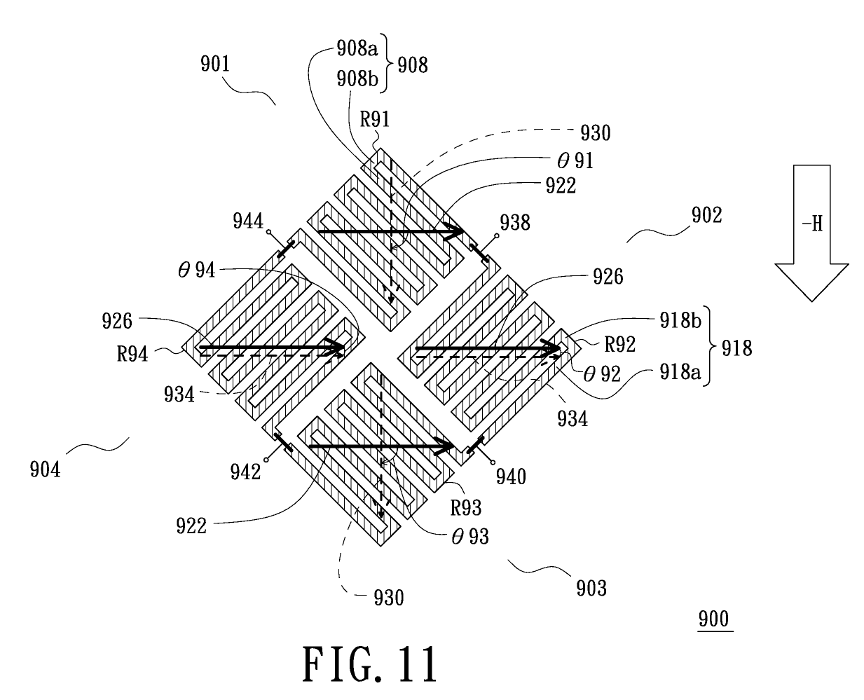

FIGS. 10 and 11 are schematic views illustrating the above spin-valve magnetoresistance sensor 900 is disposed within different external magnetic fields. Referring to FIG. 10, the spin-valve magnetoresistance sensor 900 senses an applied positive magnetic field +H, a sensing axis direction of the spin-valve magnetoresistance sensor 900 is perpendicular to the first magnetization direction 922. A positive voltage Vcc is applied to the input terminal 938, and the reference terminal 942 is grounded. A potential read from the first output terminal 940 is V1. A potential read from the second output terminal 944 is V2. Corresponding to the applied external magnetic field +H, the included angle θ91, θ93 vary from the original −45 degrees to substantially zero, and the first pair of spin-valve magnetoresistance structures 901, 903 produces same electrical resistances R91 and R93, respectively; and the included angle θ92, θ94 vary from the original 45 degrees to 90 degrees, and the second pair of spin-valve magnetoresistance structures 902, 904 produces the same electrical resistances R92 and R94, respectively.

Referring to FIG. 11, the spin-valve magnetoresistance sensor 900 senses another applied external magnetic field −H, and the input voltage, reference voltage is the same to that described above relating to FIG. 10. Corresponding to the applied external magnetic field −H, the included angle θ91, θ93 vary from the original −45 degrees to −90 degrees, and the first pair of spin-valve magnetoresistance structures 901, 903 produces the same electrical resistances R91 and R93, respectively; and the included angle θ92, θ94 vary from the original 45 degrees to substantially zero, and the second pair of spin-valve magnetoresistance structures 902, 904 produces the same electrical resistances R92 and R94, respectively.

The relation between the output voltages V1, V2 and the electrical resistances R91, R92, R93, R94 of the spin-valve magnetoresistance structures is indicated by the following formulas:

V1=R93/(R92+R93)×Vcc

V2=R94/(R91+R94)×Vcc

It is to be noted that R91 is equal to R93 and R92 is equal to R94. Replacing R93 and R94 in above formulas with R91 and R92, respectively, the following formula is obtained: V2−V1=(R92−R91)/(R92+R91)×Vcc.

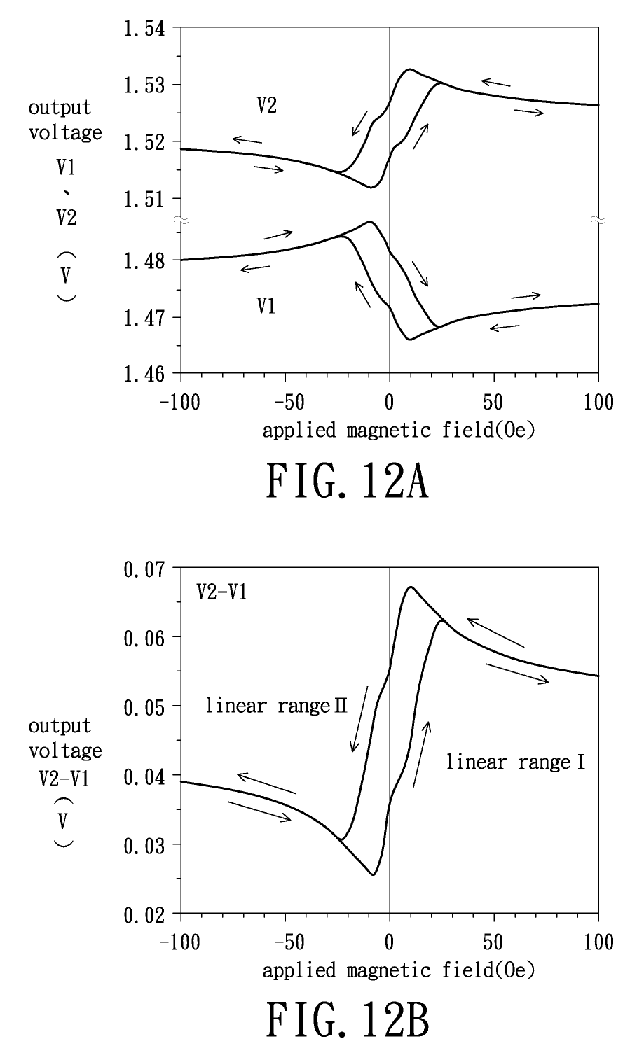

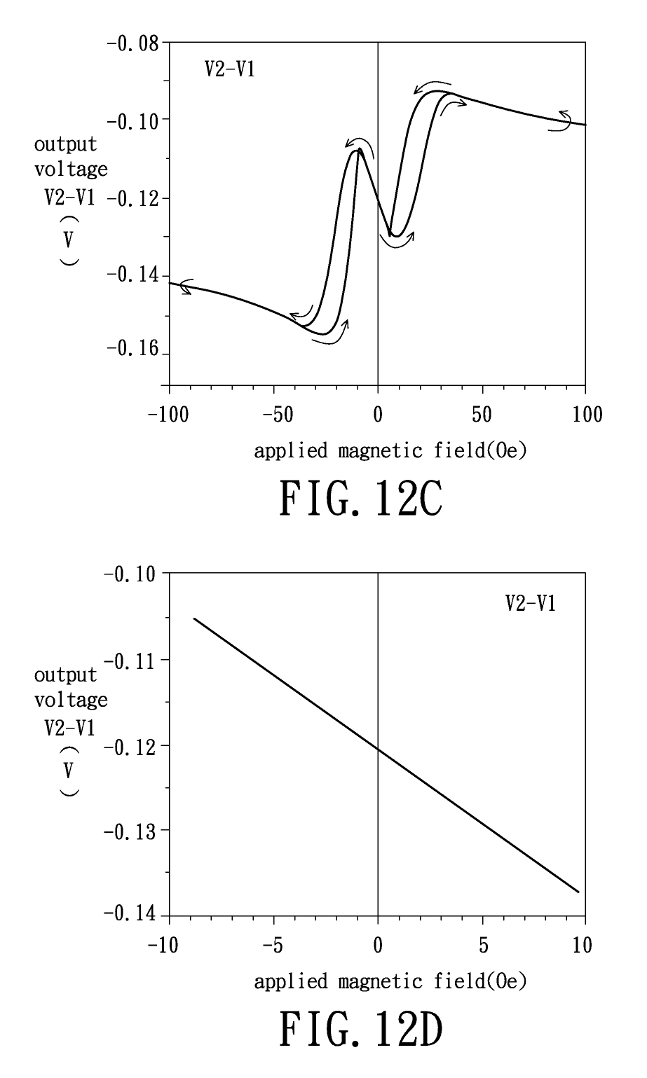

As indicated in FIGS. 10 and 11, the applied external magnetic field would change the magnetization direction of the magnetoresistance layers in the spin-valve magnetoresistance sensor 900 thereby changing the output voltages V1 and V2. FIG. 12A is a curve graph showing the output voltages V1 and V2 corresponding to different external magnetic fields. In FIG. 12, the external magnetic field gradually varies from OOe to +100 Oe, and then varies from +100 Oe to 0 Oe; after that, the magnetic field gradually varies from 0 Oe to −100 Oe, and then varies from −100 Oe to 0 Oer. Accordingly, V1 and V2 varies along the path as indicated by the arrow in FIG. 12A. FIG. 12B is a curve graph showing the relation between the output voltage difference (V2−V1) and the external magnetic field. It is to be noted that V1 and V2 can be read from FIG. 12A.

As shown in FIGS. 12A and 12B, the linear range of the spin-valve magnetoresistance sensor 900 for detecting external magnetic field is in a range from about −30 Oe to 30 Oe. If the external magnetic field exceeds this linear range, magnetic hysteresis effect occurs. For example (referring to FIG. 12B), if the external magnetic field exceeds linear range I (H>+30 Oe) and then the external magnetic field is removed, V2−V1 would fall into linear range II. At this time, a reset programming of magnetic field (H<−30 Oe) should be applied to the spin-valve magnetoresistance sensor 900 such that V2−V1 goes back to the linear range I.

In FIG. 12B, the linear range I and linear range II are well separated. In still another embodiment, parts of the linear range I and linear range II may overlap to form a single linear region in some specific magnetic field range. FIG. 12C shows the sweep curve of the output voltage difference (V2−V1) in accordance with the present embodiment. Comparing with FIG. 12B, a single linear region appeal in a specific magnetic field range of −10 Oe to +10 Oe, while beyond the specific field range (−30 Oe to −10 Oe+10 Oe to +30 Oe) the separated linear ranges I and II still exist. A more detailed measurement focusing on the specific magnetic field range (−10 Oe to +10 Oe) is shown in FIG. 12D. Since only one linear region is shown, it indicates that a resetting programming may not be required when the spin-valve magnetoresistance sensor 900 is operating within the specific magnetic field range. Different behaviors of the spin-valve magnetoresistance sensor 900 (for example, FIG. 12B vs. FIG. 12C) can be achieved by tuning the film stack and schematic layout of the spin-valve magnetoresistance structures.

According to above embodiments, the spin-valve magnetoresistance sensor includes two pairs of spin-valve magnetoresistance structures which present different magnetic and electrical response to applied external magnetic fields. The two pairs of spin-valve magnetoresistance structures have the same and fixed first magnetization direction and third magnetization direction. The second magnetization direction, the fourth magnetization direction is at an angle of 45 degrees to the first magnetization direction, the third magnetization direction, respectively when the intensity of the external magnetic field is zero, wherein the second magnetization direction is orthogonal to the fourth magnetization direction. When the intensity of the external magnetic field isn't zero, the second magnetization direction and the fourth magnetization direction would vary with the external magnetic field thereby changing the electrical resistances of the two pairs of spin-valve magnetoresistance structures. Thus, the external magnetic field can be measured according to the relation between the magnetoresistance of the spin-valve magnetoresistance sensor and the external magnetic field. As such, the coils for adjusting the magnetization direction or magnetic shielding layers on a diagonal for fixing the magnetization direction can be omitted in spin-valve magnetoresistance sensors. Thus, the structure and manufacturing process of spin-valve magnetoresistance sensors are simplified; the cost, the complexity, and the volume of spin-valve magnetoresistance sensors are also reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A spin-valve magnetoresistance structure, comprising:
a first magnetoresistance layer, having a fixed first magnetization direction;
a second magnetoresistance layer, disposed on a side of the first magnetoresistance layer and having a variable second magnetization direction, wherein the second magnetization direction is at an angle in a range from 30 to 60 degrees or from 120 to 150 degrees to the first magnetization direction when the intensity of an applied external magnetic field is zero, and the second magnetization direction varies with the external magnetic field thereby changing an included angle between the first magnetization direction and the second magnetization direction and further changing an electrical resistance of the spin-valve magnetoresistance structure; and
a spacer, disposed between the first magnetoresistance layer and the second magnetoresistance layer.

2. The spin-valve magnetoresistance structure of claim 1, further comprising a plurality of first portions and a plurality of second portions, the first portions being longer than the second portions, the first portions being connected by the second portions to construct a serpentine structure.

3. The spin-valve magnetoresistance structure of claim 2, wherein the second magnetization direction is parallel to the first portions when the intensity of the external magnetic field is zero.

4. The spin-valve magnetoresistance structure of claim 1, further comprising an exchange bias layer disposed on a side of the first magnetoresistance layer that is away from the spacer.

5. The spin-valve magnetoresistance structure of claim 1, wherein the spin-valve magnetoresistance structure is based on a mechanism selected from a group consisting of spin-valve giant magnetoresistance and spin-valve tunneling magnetoresistance.

6. The spin-valve magnetoresistance structure of claim 1, wherein the second magnetization direction is at an angle of 45 degrees to the first magnetization direction when the intensity of the external magnetic field is zero.

7. A spin-valve magnetoresistance sensor, comprising:
a first pair of magnetoresistance structures each comprising:
a first magnetoresistance layer, having a fixed first magnetization direction;
a second magnetoresistance layer, disposed on a side of the first magnetoresistance layer and having a variable second magnetization direction; and
a first spacer, disposed between the first magnetoresistance layer and the second magnetoresistance layer, wherein the second magnetization direction is at an angle in a range from 30 to 60 degrees or from 120 to 150 degrees to the first magnetization direction when the intensity of an applied external magnetic field is zero, and the second magnetization direction varies with the external magnetic field thereby changing an included angle between the first magnetization direction and the second magnetization direction and further changing a first electrical resistance of the spin-valve magnetoresistance structure; and
a second pair of magnetoresistance structures each comprising:
a third magnetoresistance layer, having a fixed third magnetization direction, wherein the third magnetization direction is the same to the first magnetization direction;
a fourth magnetoresistance layer, disposed on a side of the third magnetoresistance layer and having a variable fourth magnetization direction , wherein the fourth magnetization direction is at an angle in a range from 30 to 60 degrees or from 120 to 150 degrees to the third magnetization direction when the intensity of an applied external magnetic field is zero, the fourth magnetization direction is perpendicular to the second magnetization direction, and the fourth magnetization direction varies with the external magnetic field thereby changing an included angle between the fourth magnetization direction and the third magnetization direction and further changing a second electrical resistance of the spin-valve magnetoresistance structure; and
a second spacer, disposed between the third magnetoresistance layer and the fourth magnetoresistance layer;
wherein the first pair of magnetoresistance structure and the second pair of magnetoresistance structure are electrically connected to construct a Wheatstone bridge.

8. The spin-valve magnetoresistance sensor of claim 7, wherein the first pair of magnetoresistance structure and the second pair of magnetoresistance structure comprises a plurality of first portions and a plurality of second portions, the first portions are longer than the second portions, and the first portions are connected by the second portions to construct a serpentine structure.

9. The spin-valve magnetoresistance sensor of claim 8, wherein the second magnetization direction and the fourth magnetization direction are parallel to the first portions when the intensity of the external magnetic field is zero.

10. The spin-valve magnetoresistance sensor of claim 7, further comprising an exchange bias layer disposed on a side of the first magnetoresistance layer and the third magnetoresistance layer that is away from the first spacer and the second spacer, respectively.

11. The spin-valve magnetoresistance sensor of claim 7, wherein the spin-valve magnetoresistance structure is based on a mechanism selected from a group consisting of spin-valve giant magnetoresistance and spin-valve tunneling magnetoresistance.

12. The spin-valve magnetoresistance sensor of claim 7, wherein the second magnetization direction is at an angle of 45 degrees to the first magnetization direction when the intensity of the external magnetic field is zero.

13. The spin-valve magnetoresistance sensor of claim 7, wherein the third magnetization direction is at an angle of 45 degrees to the fourth magnetization direction when the intensity of the external magnetic field is zero.

14. The spin-valve magnetoresistance sensor of claim 7, wherein the Wheatstone bridge comprises a first output terminal having an output voltage of V1, and a second output terminal having an output voltage of V2.

15. The spin-valve magnetoresistance sensor of claim 14, wherein a voltage difference V2−V1 is in linear relation to the intensity of applied magnetic field to the spin-valve magnetoresistance sensor when the intensity of the applied magnetic field is in a range from substantially −30 Oe to substantially +30 Oe.

16. The spin-valve magnetoresistance sensor of claim 15, wherein the linear relation is reflected by two substantially parallel lines in a sweep curve of the voltage difference V2−V1 to the intensity of applied magnetic field, and the two substantially parallel lines are corresponding to an increasing trend and a decreasing trend of the intensity of applied magnetic field, respectively.

17. The spin-valve magnetoresistance sensor of claim 14, wherein a voltage difference V2−V1 is in a different linear relation to the intensity of applied magnetic field to the spin-valve magnetoresistance sensor when the intensity of the applied magnetic field is in the ranges from substantially −30 Oe to substantially −10 Oe, from substantially −10 Oe to substantially +10 Oe, from substantially +10 Oe to substantially +30 Oe, respectively.

18. The spin-valve magnetoresistance sensor of claim 17, wherein the linear relation is reflected by two substantially parallel lines in a sweep curve of the voltage difference V2−V1 to the intensity of the applied magnetic field when the intensity of the applied magnetic field is in the range from substantially −30 Oe to substantially −10 Oe, or from substantially +10 Oe to substantially +30 Oe, and the two substantially parallel lines are corresponding to an increasing trend and a decreasing trend of the intensity of applied magnetic field, respectively.

19. The spin-valve magnetoresistance sensor of claim 17, wherein the linear relation is reflected by a single line in a sweep curve of the voltage difference V2−V1 to the intensity of applied magnetic field when the intensity of the applied magnetic field is in the range from substantially −10 Oe to substantially +10 Oe.
